(19) United States
(12) Patent Application Publication
(10) Pub. No.: US 2009/0001381 A1
(43) Pub. Date: Jan. 1, 2009

(54) Semiconductor device

(75) Inventors: Toshiharu Marui, Tokyo (JP); Hideyuki Okita, Tokyo (JP); Shinichi Hoshi, Tokyo (JP); Fumihiko Toda, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY., LTD., Tokyo (JP)

(21) Appl. No.: 12/153,953

(22) Filed: May 28, 2008

(30) Foreign Application Priority Data
Jun. 27, 2007 (JP) 2007-169003

(51) Int. Cl. H01L 29/778

(52) U.S. Cl. 257/76; 257/194; 257/E29.246

(57) ABSTRACT

A semiconductor device includes a substrate, laminated layers provided on the substrate. The laminated layers include an AlGaN barrier layer as an uppermost layer. A gate electrode is provided in a channel region of the laminated layers. A source electrode and a drain electrode are provided so as to face each other via the channel region interposed therebetween. A silicon nitride film is formed to cover an exposed surface of the laminated layers exposed via the gate electrode, the source electrode and the drain electrode. The silicon nitride film has characteristics that an etching rate thereof is in a range from 1 nm per/min to 2 nm/min for an etchant in which hydrofluoric acid having a concentration of 50 weight percent and ammonium fluoride having a concentration of 40 weight percent are mixed at a mixing ratio of 1:9.

### BACKGROUND OF THE INVENTION

This invention relates to a semiconductor device and a manufacturing method thereof, and particularly relates to a high electron mobility transistor (HEMT) having excellent electric characteristics and a manufacturing method thereof.

Conventionally, a nitride semiconductor device such as an AlGaN/GaN-HEMT has a silicon nitride (SiN) film formed as a surface protection film for preventing a current collapse and enhancing power characteristics at high voltage.

However, when such a silicon nitride film is used as the surface protection film, there is a problem that a breakdown voltage of the nitride semiconductor device decreases, although the nitride semiconductor device is required to have a high breakdown voltage.

In order to solve this problem, it is proposed to employ a gate structure called as a field-plate (FP) gate structure to the AlGaN/GaN-HEMT (see, for example, Non-Patent document No. 1). The FP gate structure has been conventionally used in a GaAs-based compound semiconductor.

Non-Patent Document No. 1: Yuji Ando, Yasuhiro Okamoto, Hironobu Miyamoto, Tatsuo Nakayama, Takashi Inoue, and Masaaki Kuzuhara “Characterization of High Breakdown Voltage AlGaN/GaN Heterojunction FETs with a Field Plate Gate” Technical Report of IEICE, ED2002-214, CPM2002-105 (2002-10), pp. 29-34.

In the manufacturing method of the conventional art, the silicon nitride film as the surface protection film is grown by a plasma CVD (Chemical Vapor Deposition) method.

In this case, a surface level (i.e., a so-called AlGaN-level) is formed at the surface of the AlGaN layer covered with the silicon nitride film.

Further, the silicon nitride film formed by the plasma CVD method is an amorphous film, and therefore a level due to dangling bond may be formed in the silicon nitride film.

Moreover, in the manufacturing method of the conventional art, compound semiconductor layers are epitaxially grown on a substrate (i.e., a processing object) in film-forming equipment. Then, the substrate is taken out of the film-forming equipment, and set in plasma CVD equipment to form the silicon nitride film on the compound semiconductor layers. With such a method, the epitaxially grown layers on the substrate are exposed to an atmosphere, and therefore the exposed surface may be contaminated or oxidized.

For these causes, the semiconductor device with the silicon nitride film formed by the plasma CVD method has a problem that a current collapse and a gate leak current may easily occur.

Further, if the above described FP gate structure is applied to the AlGan/GaN-HEMT, there is another problem that high frequency characteristics are deteriorated.

In addition, if the silicon nitride film is used as the surface protection film or the gate insulation film, hydrogen existing in the silicon nitride film may cause nitrogen atoms to be dropped from the surface of the compound semiconductor layer adjacent to the silicon nitride layer. Therefore, the surface level of the compound semiconductor layer is raised, with the result that electric characteristics may be deteriorated.

In this regard, it is expected that the generation of surface level of the compound semiconductor layer can be prevented by reducing hydrogen content in the silicon nitride film (as the surface protection film or the gate insulation film), so that the deterioration of the electric characteristics can be effectively prevented.

### SUMMARY OF THE INVENTION

The present invention is intended to solve the above described problems, and an object of the present invention is to provide a semiconductor device capable of preventing a deterioration of electric characteristics.

The present invention provides a semiconductor device including a substrate, and laminated layers provided on the substrate. The laminated layers include an AlGaN barrier layer as an uppermost layer.

A gate electrode is provided in a channel region of the laminated layers. A source electrode and a drain electrode are provided so as to oppose each other via the channel region interposed therebetween.

The semiconductor device further includes a silicon nitride film as a surface protection film or a gate insulation film constituting an uppermost layer. The silicon nitride film covers a surface of the laminated layers exposed via the gate electrode, the source electrode and the drain electrode.

The silicon nitride film has characteristics that an etching rate thereof is in a range from 1 nm per/min to 2 nm/min for an etchant in which hydrofluoric acid having a concentration of 50 weight percent and ammonium fluoride solution having a concentration of 40 weight percent are mixed at a mixing ratio of 1:9.

With the above described semiconductor device, it becomes possible to use a silicon nitride film formed by a thermal CVD method whose hydrogen content is remarkably lower than a silicon nitride film formed by a conventional plasma CVD method.

Therefore, it becomes possible to lower a level generated in the silicon nitride film and a surface level of an underlying layer (for example, the AlGaN film) directly below the silicon nitride film. Accordingly, it becomes possible to effectively prevent current collapse, to reduce gate leak current, and to prevent deterioration of high frequency characteristics. As a result, a semiconductor device having high performance can be provided.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

In the attached drawings:

FIG. 1 is a sectional view of a semiconductor device according to the embodiment of the present invention;

FIG. 2 is a sectional view of another example of a semiconductor device according to the embodiment of the present invention;

FIGS. 3A, 3B and 3C are sectional views showing respective steps of a manufacturing process of the semiconductor device according to the embodiment of the present invention;

FIG. 4 is a flow chart for illustrating a manufacturing method of the semiconductor device according to a modification of the embodiment of the present invention;

FIG. 5A is a graph showing IR absorption spectrum;

FIG. 5B is an enlarged view of a part of the graph of FIG. 5A;

FIGS. 6A and 6B are graphs (1) showing current collapsing characteristics;

FIG. 7 is a graph (1) showing reverse characteristics;

FIGS. 8A and 8B are graphs (2) showing current collapsing characteristics;

FIG. 9 is a graph (2) showing reverse characteristics, and

FIGS. 10A and 10B are graphs (3) showing current collapsing characteristics.

### DETAILED DESCRIPTION OF THE PREFERRED EMBODIMENT

Hereinafter, an embodiment of the present invention will be described with reference to the attached drawings. Shapes, sizes and positions of respective components are schematically shown in the attached drawings merely for the illustrative purpose, but do not limit the scope of the present invention. Specific materials, conditions, numerical examples or the like described in the following description are merely preferred examples, but do not limit the scope of the present invention.

### <Configuration Example of Semiconductor Device>

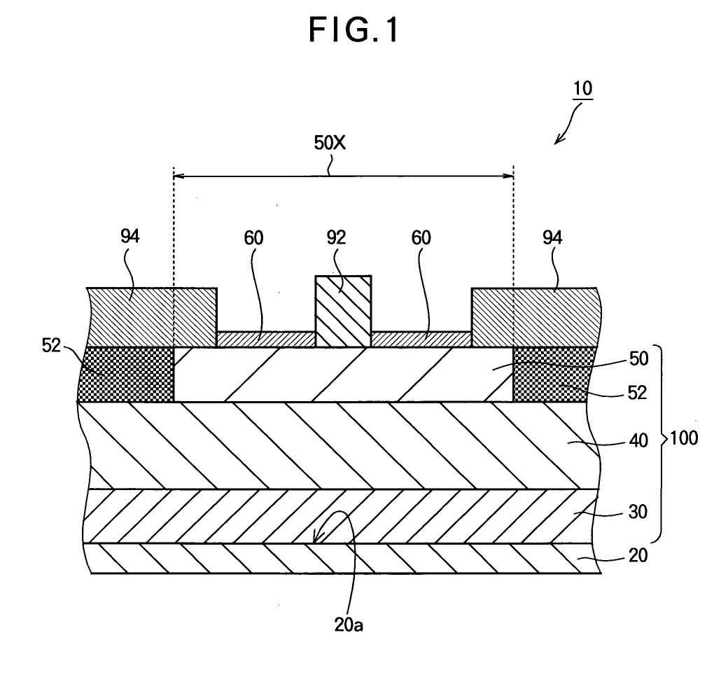

A configuration example of a semiconductor device according to the embodiment of the present invention will be described with reference to FIG. 1.

FIG. 1 is a sectional view showing the semiconductor device according to the embodiment of the present invention.

Here, an HEMT, i.e., a high electron mobility transistor will be explained as an example of the semiconductor device.

The semiconductor device 10 according to this embodiment is formed on a substrate 20. The substrate 20 can be composed of an arbitrary preferable substrate applicable to the HEMT, such as a silicon carbide substrate, a silicon substrate, a gallium nitride substrate, or a sapphire substrate.

Laminated layers 100 including a plurality of compound semiconductor layers are formed on a main surface 20a (i.e., an upper surface in FIG. 1) of the substrate 20.

The laminated layers 100 can have an arbitrary preferable configuration based on a design providing preferable electric characteristics. In the configuration example shown in FIG. 1, the laminated layers 100 include a buffer layer 30, a channel layer 40 and a barrier layer 50 which are layered on the main surface 20a of the substrate 20 in this order.

The buffer layer 30 formed on the main surface 20a of the substrate 20 can be composed of an arbitrary preferable material such as, for example, Aluminum Nitride (AlN) which is commonly used in this field.

The channel layer 40 formed on the buffer layer 30 is preferably composed of, for example, an UID (Unintentionally Doped)-GaN layer.

The barrier layer 50 formed on the channel layer 40 is preferably composed of, for example, an UID-AlGaN layer.

Two dimensional electron gas (2DEG) is to be created in the vicinity of an interface between the channel layer 40 and the barrier layer 50 during the operation of the semiconductor device 10.

A channel region 50X is provided in the laminated layers 100. The channel region 50X is isolated from other channel regions by an element isolation region 52 provided in the barrier layer 50.

The semiconductor device 10 further includes a gate electrode 92 and an ohmic electrode 94, i.e., a source electrode and a drain electrode.

Next, the gate electrode 92 and the ohmic electrode 94 will be described in detail with reference to the drawings. Materials, positions and sizes of these electrodes can be determined arbitrarily and preferably based on a design.

The gate electrode 92 is provided in the channel region 50X on the barrier layer 50, i.e., on the laminated layers 100.

The gate electrode 92 preferably has a conventional arbitrary preferable configuration applicable to the HEMT such as, for example, laminated layers of nickel (Ni) and gold (Au).

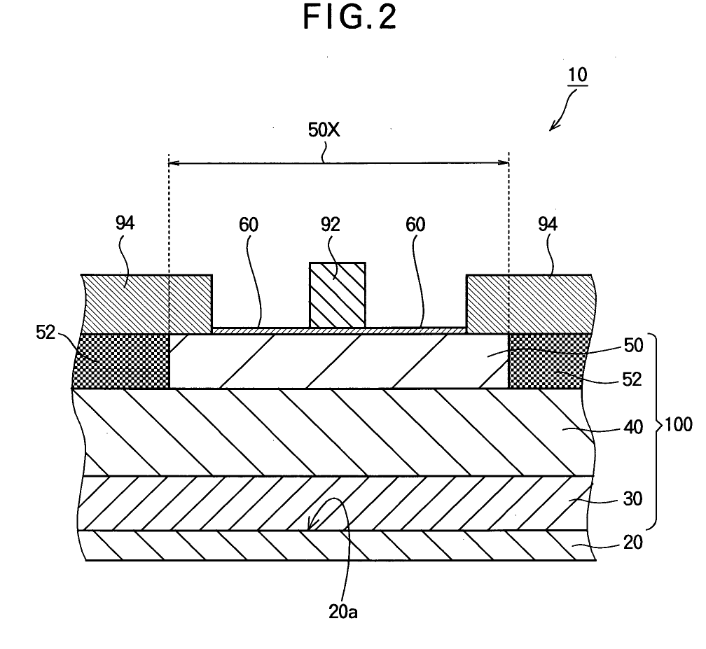

Alternatively, the gate electrode 92 can have an MIS (Metal Insulator Semiconductor) structure, as shown in FIG. 2. In this case, the gate electrode 92 is formed on the silicon nitride film 60 without contacting the barrier layer 50.

If the gate electrode 92 has the MIS structure (FIG. 2), the silicon nitride film 60 functions as a gate insulation film. Therefore, in this case, it is preferable that the silicon nitride film 60 has arbitrary preferable thickness so as to function as a gate insulation film.

Two ohmic electrodes 94 are provided on the laminated layers 100 so as to sandwich the gate electrode 92 in the gate width direction and to be distanced from the gate electrode 92. Each ohmic electrode 94 straddles the element isolation region 52 and a part of the channel region 50X so that a part of the channel region 50X between the ohmic electrodes 94 is exposed.

The respective ohmic electrodes 94 oppose each other with the channel region 50X interposed therebetween, and respectively act as a source electrode and a drain electrode.

The ohmic electrode 94 preferably has a conventional arbitrary preferable configuration applicable to the HEMT such as, for example, laminated layers of Titanium (Ti) and Aluminum (Al).

The semiconductor device 10 of this embodiment includes a silicon nitride film 60.

The silicon nitride film 60 covers the exposed surface of the laminated layers 100 (i.e., the barrier layer 50) exposed via the ohmic electrodes 94 (i.e., the source electrode and the drain electrode) and the gate electrode 92.

As shown in FIG. 1, when the silicon nitride film 60 is used as a surface protection film, it is preferable that the silicon nitride film 60 has a thickness in a range approximately from 50 nm to 100 nm.

If the gate electrode 92 has the MIS structure (FIG. 2) as described above, the silicon nitride film 60 functions as a gate insulation film. In such a case, it is preferable that the thickness of the silicon nitride film 60 is, for example, approximately 5 nm.

The silicon nitride film 60 of this embodiment has following characteristics. That is, the silicon nitride film 60 has an etching rate (i.e., a remarkably small etching rate) in a range from 1 nm/min to 2 nm/min for an etchant of buffered hydrogen fluoride. In this case, the silicon nitride film 60 is formed to have remarkably low nitrogen content.

The above described buffered hydrogen nitride is preferably formed by mixing hydrofluoric acid having a concentration of 50 weight percent and ammonium fluoride solution having a concentration of 40 weight percent at a mixing ratio of 1:9.

The silicon nitride film 60 used in this embodiment has lower hydrogen content and higher nitrogen content, compared with a silicon nitride film formed by a conventional plasma CVD method, the detailed description given later.

As described above, the semiconductor device 10 of the embodiment of the present invention uses the silicon nitride film 60 composed of a silicon nitride film having a remarkably low etching rate for buffered hydrogen fluoride (i.e., a silicon nitride film having lower hydrogen content).

Therefore, the level in the silicon nitride film can be lowered. Thus, it becomes possible to effectively prevent current collapse, to reduce gate leak current, and to prevent deterioration of high frequency characteristics. As a result, a semiconductor device having high performance can be obtained.

### <Manufacturing Method of Semiconductor Device>

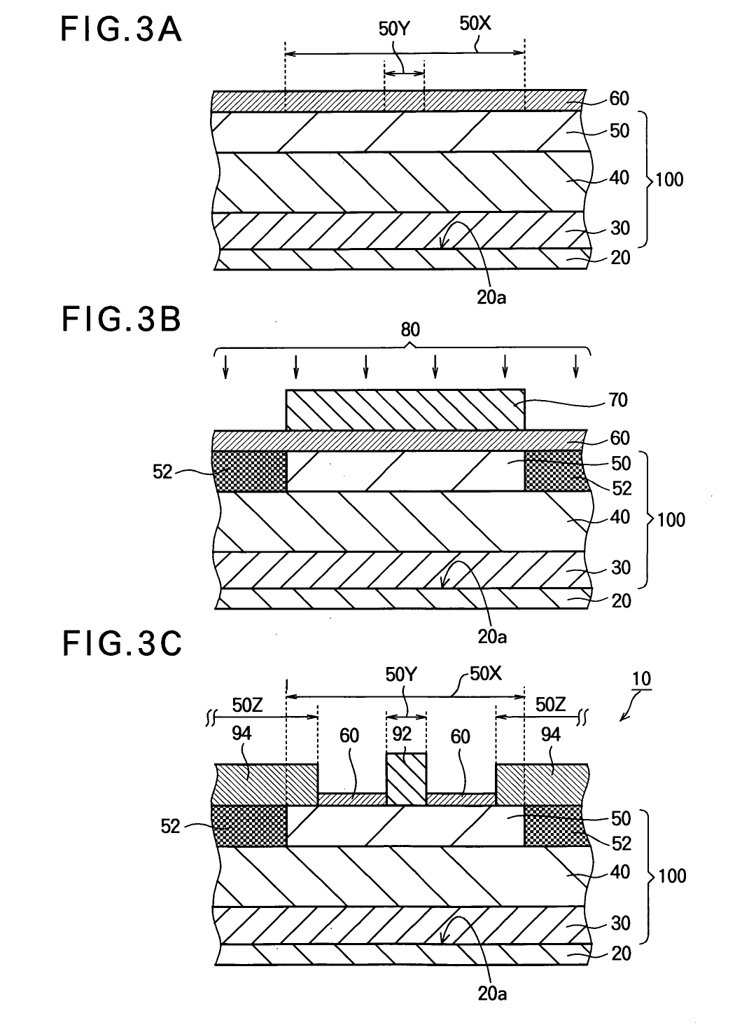

A manufacturing method of the semiconductor device 10 (having been described with reference to FIG. 1) will be described with reference to FIGS. 3A, 3B and 3C.

FIGS. 3A, 3B and 3C are sectional views showing respective steps of a manufacturing process of the semiconductor device according to the embodiment of the present invention.

The manufacturing process of this embodiment is characterized in that the forming process of the silicon nitride film 60 is performed successively and continuously after the forming process of the laminated layers 100 (including a plurality of compound semiconductor layers) in the same equipment. Throughout the entire manufacturing process, the laminated layers 100 and the silicon nitride film 60 are not exposed to an external environment, i.e., an atmosphere outside the equipment.

The following description of the manufacturing method will be made with reference to the semiconductor device configured to obtain experimental data as described later. However, this embodiment of the present invention is not limited to such a configuration.

First, the substrate 20 which is a silicon carbide substrate is prepared as shown in FIG. 3A.

Then, the laminated layers 100 including a plurality of layers are formed on the main surface 20a of the substrate 20. The laminated layers 100 are formed by epitaxially growing a plurality of layers of compound semiconductors using, for example, a conventional MOCVD (Metal Organic Chemical Vapor Deposition) method under arbitrary preferable conditions.

In this example, preferably, a buffer layer 30 (as a component of the laminated layers 100) is formed first. The buffer layer 30 is preferably composed of aluminum nitride (AlN) layer. The aluminum nitride layer can be formed by a conventional arbitrary preferable manufacturing process.

Next, the UID-GaN layer as the channel layer 40 is formed on the buffer layer 30. The UID-GaN layer is preferably formed using tri-methyl gallium (TMGa) as group-III material, ammonia (NH₃) as group-V material, hydrogen gas (H₂) and nitrogen gas (N₂) as reactant gases, and tri-methyl aluminum (TMAI).

In this example, the UID-GaN layer is formed under the condition that the temperature is approximately 1170° C., the pressure is approximately 100000 Pa (760 Torr), the total gal flow rate is approximately 42 slm (standard liter/min), the flow rate of TMGa is 88 μmol/min, and the flow rate of NH₃ is 5 slm. The thickness of the UID-GaN layer is in a range from 1 μm to 2 μm.

In this regard, it is preferable to use a reduced pressure condition substantially in a range from, for example, 50 Torr (approximately, 6665 Pa) to 760 Torr (approximately, 100000 Pa).

Next, the barrier layer 50 is preferably formed on the channel layer 40. In this example, the barrier layer 50 is an UID-AlGaN layer. In this process, a tri-methyl gallium and tri-methyl aluminum are used as group-III material, ammonia is used as group-V material, and hydrogen gas and nitrogen gas are used as reactant gas.

In this example, the UID-AlGaN layer is formed under the condition that the temperature is approximately 1170° C., the pressure is approximately 100000 Pa, the total gal flow rate is approximately 48 slm, the flow rate of TMGa is 22 μmol/min, and the flow rate of NH₃ is 6 slm. The thickness of the UID-AlGaN layer is in a range from 15 nm to 25 nm.

The laminated layers 100 are formed under the above described conditions.

Then, the silicon nitride film 60 is formed. In this example, the forming process of the silicon nitride film 60 is performed after the forming process of the laminated layers 100 using the same MOCVD equipment, i.e., in the same chamber without exposing the inside of the chamber to the atmosphere.

First, the replacement of the reactant gas is performed. For this purpose, preferably hydrogen gas is introduced into the chamber at a flow rate of 15 slm, and nitrogen gas is introduced into the chamber at a flow rate of 14 slm, so that the tri-methyl gallium, tri-methyl aluminum and ammonia (having been used as a material for forming the laminated layers 100) are ejected out of the chamber.

Next, preferably, the temperature in the chamber is varied from approximately 1170° C. (suitable for forming the UID-AlGaN layer) and adjusted in a range approximately from 700° C. to 800° C. The time required for adjustment of the temperature in the chamber is approximately 5 minutes.

Then, the reactant gas is introduced into the chamber. In this example, dichlorosilane gas at a concentration of 0.7% is introduced into the chamber at a flow rate of 100 sccm (standard cc/min), and ammonia gas at a concentration of 100% is introduced into the chamber at a flow rate of 6 slm, so as to form the silicon nitride film 60.

In this way, the forming process of the silicon nitride film 60 of this embodiment is performed using a thermal CVD method.

Next, the element isolation region 52 is formed as shown in FIG. 3B. The element isolation region 52 is formed out of the channel region 50X, and therefore a resist pattern 70 is first formed to cover the channel region 50X. The resist pattern 70 is formed by patterning a conventional arbitrary preferable resist material using a conventional photolithographic process.

Next, an ion injection process is performed using the resist pattern 70 as a mask. In the ion injection process, argon ion (Ar⁺) as the ion 80 is injected into the barrier layer 50 using a conventional injection method.

With this process, the element isolation region 52 is formed on a partial region of the barrier layer 50 directly below the silicon nitride film 60 exposed via the resist pattern 70.

Next, as shown in FIG. 3C, the gate electrode 92 and the ohmic electrode 94 are formed on the laminated layers 100, i.e., on respective partial regions of the barrier layer 50 and the element isolation region 52.

First, partial regions of the silicon nitride film 60 where the gate electrode 92 and the ohmic electrode 94 are to be formed are removed. To be more specific, a gate-electrode-forming region 50Y of the silicon nitride film 60 which is preliminary defined in the channel region 50X is removed. Further, partial regions 50Z of the silicon nitride film 60 on both sides of the gate-electrode-forming region 50Y (and apart from the gate-electrode-forming region 50Y in the longitudinal direction of the channel) are also removed so that the partial region 50Z straddles the channel region 50X and the element isolation region 52. In this regard, two partial regions 50Z are formed on both sides of the gate-electrode-forming region 50Y.

The removing of partial regions (50Y, 50Z) of the silicon nitride film 60 is performed by a conventional photolithographic process using a mask pattern (i.e., covering non-removal regions of the silicon nitride film so that to-be-removed regions of the silicon nitride film are exposed), and by a conventional etching process to remove the removal portions.

The etching process is preferably performed by a dry etching process such as an inductive coupled plasma reactive ion etching.

Next, the ohmic electrode 94 (i.e., the source electrode and the drain electrode) is formed on the exposed barrier layer 50, and in the above described partial regions 50Z straddling the channel region 50X and the element isolation region 52 so that the ohmic electrode 94 includes two partial regions opposing each other with the channel region 50X interposed therebetween.

The ohmic electrode 94 is preferably formed of, for example, titanium (Ti) and aluminum (Al) using a conventional mask process and a conventional electron beam deposition process under arbitrary preferable conditions.

To be more specific, a titanium film is formed to a thickness of 15 nm, and then an aluminum film is formed on the titanium film to a thickness of 200 nm. Further, a conventional lift-off process is performed. Then, an annealing process is performed under the nitrogen atmosphere so as to form ohmic contact.

The gate electrode 92 is formed on the exposed barrier layer 50 in the gate-electrode-forming region 50Y using the conventional electron beam deposition method as was described in the forming process of the ohmic electrode 94. The gate electrode 92 is formed of laminated layers of arbitrary preferable material such as laminated layers of nickel (Ni) and gold (Au).

In this regard, experimental data (described later) are obtained using the semiconductor device having a pattern in which the gate electrode 92 has the width of approximately 10 μm.

According to the manufacturing method of the semiconductor device of this embodiment, the silicon nitride film is formed by the above described thermal CVD process, and therefore the hydrogen content in the silicon nitride film can be restricted to be very low.

Further, according to the above described manufacturing method, the silicon nitride film is formed successively and continuously after the epitaxially grown layers such as AlGaN layer are formed in the same chamber, and therefore the laminated layers 100 (i.e., the epitaxially grown layers) are not exposed to external environment in the film forming process of the silicon nitride film.

As described above, it becomes possible to prevent the oxidization and contamination of the exposed surface of the epitaxially grown layers in the film formation process of the silicon nitride film, and therefore the exposed epitaxially grown layers can be kept sufficiently clean. Therefore, it becomes possible to effectively prevent the deterioration of the electric characteristics due to the oxidization and contamination of the exposed surface of the epitaxially grown layers.

Therefore, according to the manufacturing method of the embodiment, it becomes possible to effectively prevent current collapse, to reduce gate leak current, and to prevent deterioration of high frequency characteristics. Thus, the semiconductor device having high performance can be obtained.

### Modification.

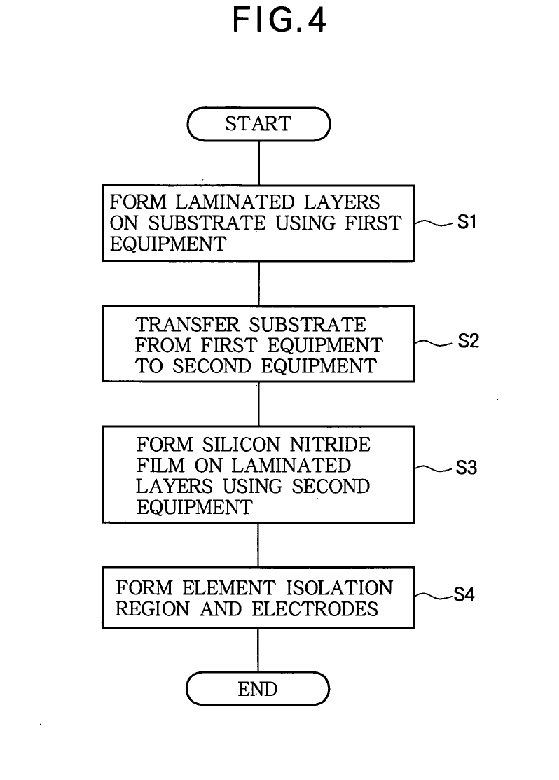

FIG. 4 is a flow chart illustrating a manufacturing method of a semiconductor device according to a modification of the embodiment of the present invention. In this modification, the laminated layers 100 are formed on the substrate 20 in the MOCVD equipment or the like which is referred to first equipment (Step S1). Then, the substrate 20 on which the laminated layers 100 are formed is taken out of the first equipment, and is transferred to different equipment which is referred to second equipment (Step S2). Then, the silicon nitride film 60 is formed on the laminated layers 100 using the thermal CVD method in the second equipment (Step S3). Thereafter, the element isolation region 52, the gate electrode 92 and the ohmic electrode 94 are formed as in the above described embodiment (Step S4).

The film forming conditions in the respective processes are the same as those of the above described embodiment, and therefore a duplicate description is omitted.

According to the modification, the substrate 20 (i.e., a processing object) is exposed to external environment when the substrate 20 is transferred from the first equipment (in which the laminated layers 100 are formed on the substrate 20) to the second equipment for forming the silicon nitride film 60.

Therefore, during the transferring of the substrate 20, there is a possibility that the exposed surface of the laminated layers 100 (i.e., the compound semiconductor layer) may be oxidized or contaminated.

However, the silicon nitride film 60 is formed by the thermal CVD process in the step S2. Therefore, even when the exposed surface of the laminated layers 100 is oxidized or contaminated by being exposed to external environment, the surface of the laminated layers 100 is cleaned by the reactant gas including ammonia during the thermal CVD process, and becomes a clean surface. Accordingly, a surface level of the uppermost layer of the laminated layers 100 can be lowered. Therefore, as in the above described embodiment, it becomes possible to provide the semiconductor device having high performance with the aid of the silicon nitride film 60 whose hydrogen content is low.

### <Electric Characteristics of Semiconductor Device>

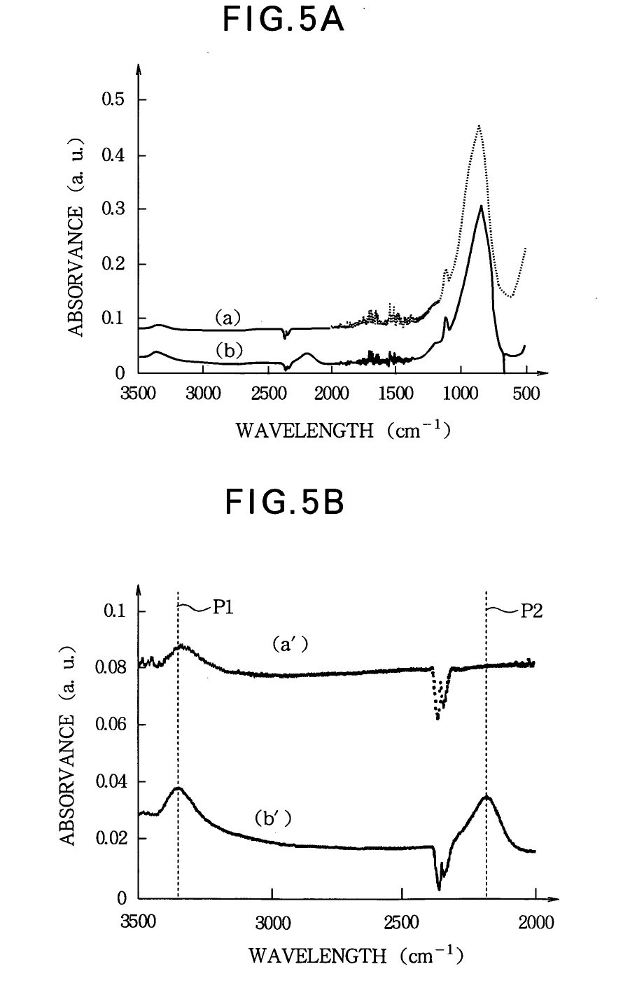

Electric characteristics of the above configured semiconductor device (i.e., the semiconductor element) according to the embodiment of the present invention will be described with reference to FIGS. 5A through 10B.

For reference, a semiconductor device (hereinafter referred to as a reference semiconductor device) is prepared, which has a silicon nitride film formed by a plasma CVD method. Except the silicon nitride film formed by the plasma CVD method, the reference semiconductor device has the same configuration (such as layers and electrodes) and the same film thicknesses as those of the above described semiconductor device according to the embodiment of the present invention.

The reference semiconductor device has a silicon nitride film as a surface protection film formed at a temperature of 300° C. and at a pressure of approximately 120 Pa (900 mTorr) while introducing silane gas at a flow rate of 35 sccm, ammonia gas at a flow rate of 5.5 sccm and N₂ carrier gas at a flow rate of 1500 sccm into the chamber.

FIG. 5A is a graph showing IR absorption spectrum, and FIG. 5B is an enlarged view of a part of the graph of FIG. 5A.

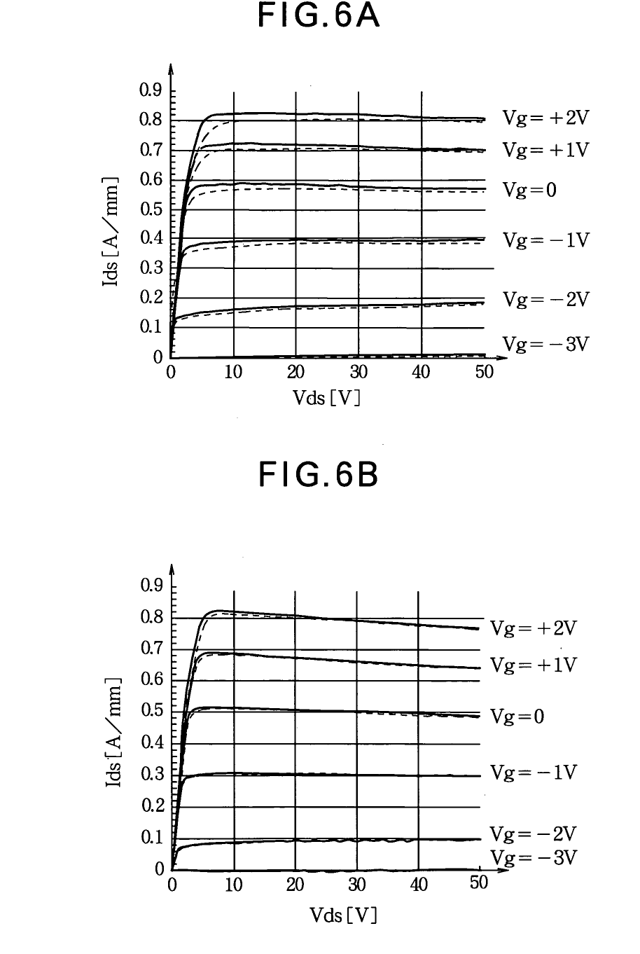

FIGS. 6A and 6B are graphs (1) showing current collapse characteristics.

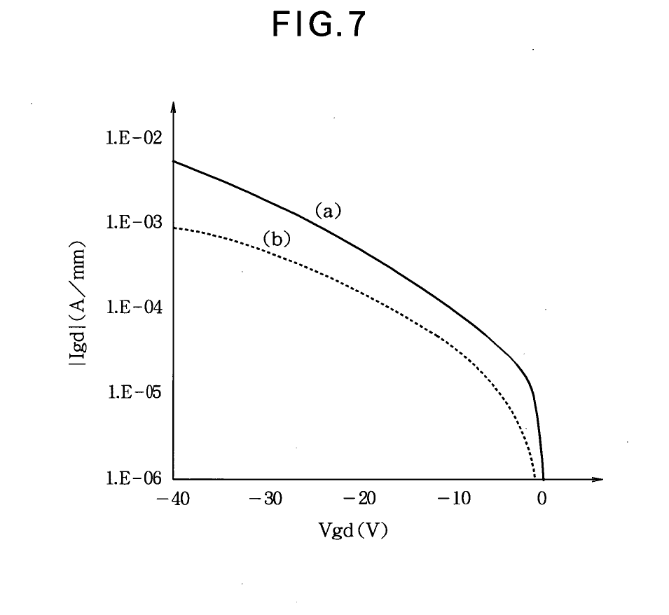

FIG. 7 is a graph (1) showing reverse characteristics.

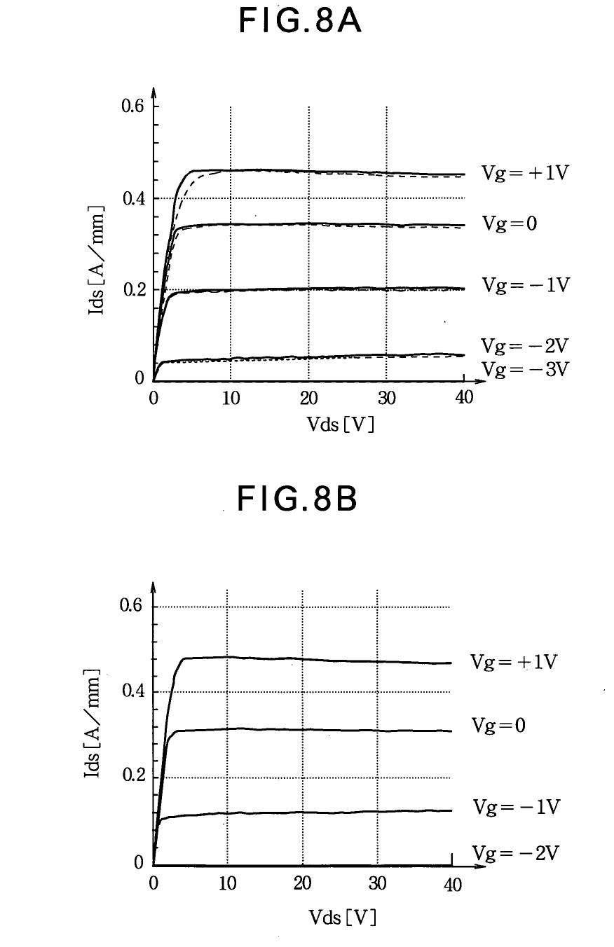

FIGS. 8A and 8B are graphs (2) showing current collapse characteristics.

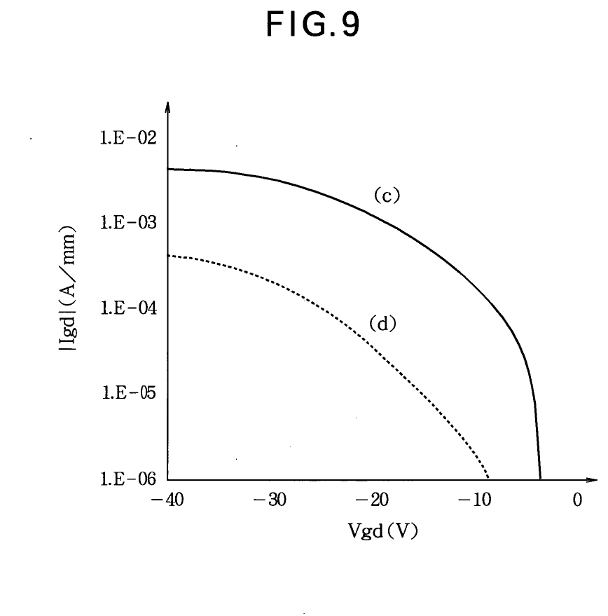

FIG. 9 is a graph (2) showing reverse characteristics.

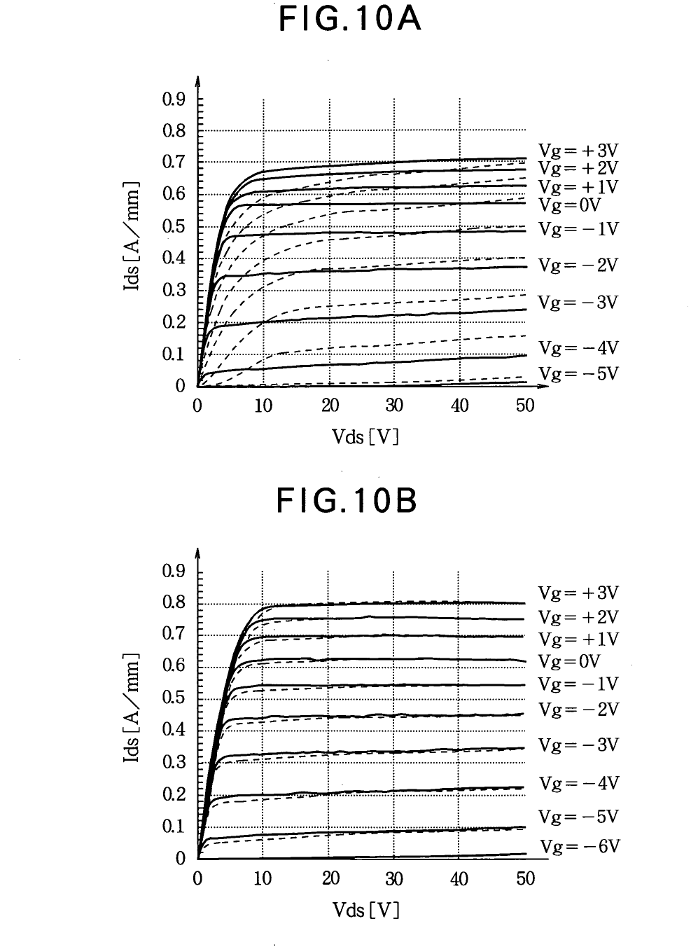

FIGS. 10A and 10B are graphs (3) showing current collapse characteristics.

With reference to FIGS. 5A and 5B, IR absorption spectrum data of the silicon nitride film (i.e., the surface protection film) will be described. The data is obtained using a conventional FT-IR (Fourier Transform Infrared) method.

In FIGS. 5A and 5B, the horizontal axis represents wavelengths (unit: cm⁻¹), and the vertical axis represents absorbance (unit: arbitrary unit).

A line (a) in FIG. 5A and a line (a′) in FIG. 5B indicate data of the semiconductor device according to the embodiment of the present invention. A line (b) in FIG. 5A and a line (b′) in FIG. 5B indicate data of the above described reference semiconductor device.

In FIG. 5B, peaks of the lines (a′) and (b′) near the intersections with a dashed line P1 correspond to nitrogen-hydrogen (N—H) bonding, and peaks near the intersections with a dashed line P2 correspond to silicon-hydrogen (Si—H) bonding.

By comparing the lines (a′) and (b′) shown in FIG. 5B, it is understood that the peak of N—H bonding and the peak of Si—H bonding of the line (a′) are lower than those of the line (b′). Therefore, it is understood that the peak strengths of N—H bonding and Si—H bonding of the silicon nitride film according to the embodiment of the present invention are lower than those of the silicon nitride film of the reference semiconductor device.

From this result, it is understood that the hydrogen content of the silicon nitride film formed by the thermal CVD method according to the embodiment is remarkably lower than the silicon nitride film formed by the conventional plasma CVD method.

A peak strength ratio is calculated by dividing the peak strength of N—H bonding by peak strength of Si—H bonding, and is used as a measure of a composition ratio of nitrogen. The peak strength ratio of the silicon nitride film formed by the thermal CVD method according to the embodiment of the present invention is approximately 10. In contrast, the peak strength ratio of the silicon nitride film formed by the conventional plasma CVD method is 0.5. Therefore, the composition ratio of nitrogen in the silicon nitride film formed by the thermal CVD method according to the embodiment is 20 times that of the silicon nitride film formed by the conventional plasma CVD method.

From this result, it is understood that the silicon nitride film formed by the thermal CVD method according to the embodiment of the present invention has low hydrogen content and has high composition ratio of nitrogen.

Next, current collapse characteristics of the HEMT provided with the silicon nitride film (as the surface protection film) formed by the thermal CVD method will be described with reference to FIGS. 6A and 6B.

FIG. 6A shows current collapse characteristics of the reference semiconductor device having the surface protection film (i.e., the silicon nitride film) formed by the plasma CVD method under the above described conditions. FIG. 6B shows current collapse characteristics of the semiconductor device having the surface protection film (i.e., the silicon nitride film) formed by the thermal CVD method according to the embodiment of the present invention under the above described conditions.

The current collapse characteristics are evaluated by applying sweeping pulse voltage. A pulse signal having a period of 60 msec and a pulse width of 6 msec is used.

In each of FIGS. 6A and 6B, the horizontal axis represents source-drain voltage Vds (unit: V), and the vertical axis represents source-drain current Ids (unit: A/mm). The value of gate voltage Vg is also shown in FIGS. 6A and 6B.

Further, in each of FIGS. 6A and 6B, a solid line indicates I-V characteristics measured by applying a gate voltage Vg and a source-drain voltage Vds as the pulse signal, and a broken line indicates stress I-V characteristics measured by applying a stress voltage in a range from −5 V to 40 V so that electrical charge is easily generated at a surface level of the laminated layers (so that a drop of drain current easily occurs due to current collapse) before the application of the gate voltage Vg and the source-drain voltage Vds.

By comparing FIGS. 6A and 6B, it is understood that the difference between the solid line and the broken line (for the same value of source-drain voltage Vds) of the semiconductor device having the surface protection film formed by the thermal CVD method according to this embodiment of the present invention (FIG. 6B) is smaller than that of the reference semiconductor device (FIG. 6A). Therefore, it is understood that the drop of the source-drain current is prevented in the semiconductor device having the surface protection film formed by the thermal CVD method according to the embodiment of the present invention.

Reverse characteristics of the surface protection film (i.e., the silicon nitride film) according to the embodiment of the present invention will be described with reference to FIG. 7.

FIG. 7 is a graph showing reverse characteristics of the reference semiconductor device (a) and the semiconductor device according to the embodiment of the present invention (b) having been described with reference to FIGS. 6A and 6B.

In FIG. 7, the horizontal axis represents gate-drain voltage Vgd (unit: V), and the vertical axis represents the logarithm of absolute value of gate-drain current Igd (unit: A/mm).

From FIG. 7, it is understood that the gate leak current is remarkably reduced in the semiconductor device (b) having the surface protection film formed by the thermal CVD method according to the embodiment of the present invention, compared with the reference semiconductor device (a).

Next, current collapse characteristics of the semiconductor device according to the above described modification (FIG. 4) of the present invention will be described. The semiconductor device according to the modification has the surface protection film (i.e., the silicon nitride film) formed on the laminated layers after the substrate is exposed to external environment after the laminated layers are formed on the substrate.

FIG. 8A is a graph showing current collapse characteristics of the reference semiconductor device (c) having the surface protection film formed by the plasma CVD method after the substrate is exposed to external environment after the laminated layers are formed on the substrate. FIG. 8B is a graph showing current collapse characteristics of the semiconductor device (d) according to the modification of the embodiment having the surface protection film formed by the thermal CVD method after the substrate is exposed to external environment after the laminated layers are formed on the substrate.

In each of the FIGS. 8A and 8B, the horizontal axis represents source-drain voltage Vds (unit: V), and the vertical axis represents source-drain current Ids (unit: A/mm). The value of gate voltage Vg is also shown in FIGS. 8A and 8B.

The method for evaluating current collapse characteristics is the same as that described with reference to FIGS. 6A and 6B. Further, FIGS. 8A and 8B are illustrated in the same manner as FIGS. 6A and 6B.

By comparing FIGS. 8A and 8B, it is understood that the difference between the solid line and the broken line (for the same value of source-drain voltage Vds) of the semiconductor device (d) having the surface protection film formed by the thermal CVD method is smaller than that of the reference semiconductor device (c). Therefore, it is understood that the drop of the drain current is prevented in the semiconductor device (d) having the surface protection film formed by the thermal CVD method.

FIG. 9 is a graph showing reverse characteristics of the reference semiconductor device (c) and the semiconductor device (d) according to the modification of the embodiment having been described with reference to FIGS. 6A and 6B.

In FIG. 9, the horizontal axis represents gate-drain voltage Vgd (unit: V), and the vertical axis represents the logarithm of absolute value of gate-drain current Igd (unit: A/mm).

From FIG. 9, it is understood that the gate leak current is remarkably reduced in the semiconductor device (d) having the surface protection film formed by the thermal CVD method according to the modification of the embodiment, compared with the reference semiconductor device (c).

Next, current collapse characteristics of the HEMT having MIS structure (FIG. 2) having the silicon nitride film as a gate insulation film formed by the thermal CVD method according to the embodiment of the invention will be described with reference to FIGS. 10A and 10B.

FIG. 10A is a graph showing current collapse characteristics of the reference semiconductor device (e) having the gate insulation film formed by the plasma CVD method after the substrate is exposed to external environment after the laminated layers are formed. FIG. 10B is a graph showing current collapse characteristics of the semiconductor device (f) having the gate insulation film formed by the thermal CVD method subsequently and continuously after the laminated layers are formed using the same equipment (i.e., in the same chamber).

In each of FIGS. 10A and 10B, the horizontal axis represents source-drain voltage Vgs (unit: V), and the vertical axis represents source-drain current Igs (unit: A/mm). The value of gate voltage Vg is also shown in FIGS. 10A and 10B.

The method for evaluating current collapse characteristics is the same as that described with reference to FIGS. 6A and 6B. Further, FIGS. 10A and 10B are illustrated in the same manner as FIGS. 6A and 6B.

By comparing FIGS. 10A and 10B, it is understood that the difference between the solid line and the broken line of the semiconductor device (f) having the gate insulation film formed by the thermal CVD method according to the embodiment of the present invention is smaller than that of the reference semiconductor device (e). Therefore, it is understood that the drop of the source-drain current is prevented in the semiconductor device (f) having the gate insulation film formed by the thermal CVD method.

With the semiconductor device of the present invention (which is particularly suitable for an HEMT), a surface level of a layer (particularly, an uppermost layer) adjacent to the silicon nitride film can be lowered, and therefore it becomes possible to effectively prevent current collapse, to reduce gate leak current and to prevent deterioration of high frequency characteristics.

Further, according to the manufacturing method of the present invention, it becomes possible to effectively manufacture the semiconductor device having the above described advantages.

The present invention also provides a manufacturing method of a semiconductor device.

In the manufacturing method of according to the present invention, first, a substrate is prepared.

Next, laminated layers are formed on the substrate. The laminated layers include a buffer layer formed on the substrate, a GaN channel layer formed on the buffer layer, and an AlGaN barrier layer formed on the GaN channel layer. Further, a gate-electrode-forming region and a channel region are defined in the laminated layers.

Then, a silicon nitride film is formed on the laminated layers including the gate-electrode-forming region and the channel region. The silicon nitride film has characteristics that an etching rate thereof is in a range from 1 nm per/min to 2 nm/min for an etchant in which hydrofluoric acid having a concentration of 50 weight percent and ammonium fluoride solution having a concentration of 40 weight percent are mixed at a mixing ratio of 1:9.

Next, a resist pattern is formed to cover the channel region of the silicon nitride film.

Using the resist pattern as a mask, ion is injected into a part of the AlGaN barrier layer directly below the exposed silicon nitride film outside the channel region, so as to form an element isolation region.

Then, the resist pattern is removed.

Further, a part of the silicon nitride film straddling the channel region and the element isolation region is removed, so as to form a source electrode and a drain electrode on the exposed AlGaN barrier layer so that the source electrode and the drain electrode oppose each other via the channel region interposed therebetween.

Then, a gate electrode is formed in the channel region.

With the above described manufacturing method of the semiconductor device, the silicon nitride film can be formed using a thermal CVD method, and therefore it becomes possible to keep clean the exposed surface of the epitaxial grown layers on which the silicon nitride film is to be formed.

In this state, the formation of the epitaxially grown layers such as the AlGaN layer can be performed successively and continuously after the formation of the silicon nitride film.

Therefore, it becomes possible to prevent the oxidization or contamination of the exposed surface of the epitaxially grown layers when the silicon nitride film is to be formed, and to lower the surface level of the underlying layer (for example, the AlGaN film) directly below the silicon nitride film. Accordingly, a semiconductor device having high performance can be provided.

In the above described method, it is preferable that the forming process of the AlGaN barrier layer and the forming process of the silicon nitride film are continuously performed using the same equipment which is not exposed to an external environment.

Further, in the forming process of the gate electrode, it is preferable to form an opening in the silicon nitride film, and to form the gate electrode so as to penetrate the silicon nitride film to contact the AlGaN barrier layer.

Furthermore, in the forming process of the gate electrode, it is preferable to form the gate electrode on the silicon nitride film.

While the preferred embodiments of the present invention have been illustrated in detail, it should be apparent that modifications and improvements may be made to the invention without departing from the spirit and scope of the invention as described in the following claims.

What is claimed is:

1. A semiconductor device comprising:
a substrate;
laminated layers provided on the substrate, said laminated layers including an AlGaN barrier layer as an uppermost layer;
a gate electrode provided in a channel region of said laminated layers;
a source electrode and a drain electrode provided so as to oppose each other via said channel region interposed therebetween, and
a silicon nitride film that covers an exposed surface of said laminated layers exposed via said gate electrode, said source electrode and said drain electrode,
wherein said silicon nitride film has characteristics that an etching rate thereof is in a range from 1 nm per/min to 2 nm/min for an etchant in which hydrofluoric acid having a concentration of 50 weight percent and ammonium fluoride having a concentration of 40 weight percent are mixed at a mixing ratio of 1:9.

2. The semiconductor device according to claim 1, wherein said substrate is one of a silicon carbide substrate, a silicon substrate, a gallium nitride substrate and a sapphire substrate.

3. The semiconductor device according to claim 1, wherein said laminated layers comprise:
a buffer layer provided on said substrate;
a GaN channel layer provided on said buffer layer, and
an AlGaN barrier layer provided on said GaN channel layer.

4. The semiconductor device according to claim 1, wherein said gate electrode is provided so as to penetrate said silicon nitride film and contact said AlGaN barrier layer.

5. The semiconductor device according to claim 1, wherein said gate electrode is provided on said silicon nitride film.
